(19) United States
(12) Patent Application Publication
(10) Pub. No.: US 2009/0242018 A1
(43) Pub. Date: Oct. 1, 2009

(54) THIN-FILM SOLAR CELL AND FABRICATION METHOD THEREOF

(76) Inventors: Seh-Won Ahn, Seoul (KR); Young-Joo Eo, Seoul (KR); Kwy-Ro Lee, Seoul (KR); Don-Hee Lee, Anyang-Si (KR); Heon-Min Lee, Seongnam-Si (KR)

Correspondence Address: BIRCH STEWART KOLASCH & BIRCH, PO BOX 747, FALLS CHURCH, VA, 22040-0747, US

(21) Appl. No.: 12/158,028

(22) PCT Filed: Apr. 11, 2007
(86) PCT No.: PCT/KR07/01750

§ 371 Date: Jun. 18, 2008

(30) Foreign Application Priority Data
Apr. 12, 2006 (KR) 10-2006-0033344

(51) Int. Cl. H01L 31/0368; H01L 31/0376; H01L 21/20; H01L 31/18

(52) U.S. Cl. 136/255; 136/256; 438/96; 438/97; 257/E21.133; 257/E31.047; 257/E31.043

(57) ABSTRACT

The present invention relates to a thin-film solar cell and a fabrication method thereof, the solar cell having a structure that a glass substrate, a transparent conductive oxide, a multi-junction solar cell layer and an electrode layer are stacked, wherein a first solar cell layer and a second solar cell layer, which are in a multi-junction, are electrically connected with each other in parallel, and one or more unit cells connected in parallel are grouped to be electrically connected with each other in series. According to the present invention, a thin-film solar cell having a unit cell in a structure that two solar cell layers having different characteristics are connected with each other in parallel, and having a structure that several unit cells are connected with each other in series, can achieve higher output and efficiency than a thin-film solar cell having a structure that several solar cell layers are connected in series.

### TECHNICAL FIELD

The present invention relates to a thin-film solar cell and a fabrication method thereof, and more particularly to a thin-film solar cell and a fabrication method thereof, capable of improving a connection between neighboring unit cells so that dissipation of electrical power can be minimized and photoelectric conversion efficiency can be improved, in a solar cell with unit cells in a structure that two solar cell layers having large difference in circuit-short current due to different characteristics are stacked.

### BACKGROUND ART

A great deal of research on a solar cell as a source for clean energy has been carried out for several decades. As material of a solar cell, group VI based material such as a single crystalline silicon, a polycrystalline silicon, an amorphous silicon, amorphous SiC, amorphous SiN, amorphous SiGe and amorphous SiSn, etc., group III-V based material such as gallium arsenic (GaAs), aluminum gallium arsenic (AlGaAs) and indium phosphorus (InP), etc., and group II-Vi based compound semiconductor such as CdS, CdTe and Cu₂S, etc., have been used up to now. Also, as structure of a solar cell, a pn structure including a rear electric field type, a pin structure, a hetero junction structure, a Schottky structure, and a multi-junction structure including tandem or a vertical junction type, and the like have been adopted.

In general, the characteristics of high photoelectric conversion efficiency, low manufacturing cost and short energy recovery term are requested for a solar cell.

The solar cell currently commercialized using the single crystalline silicon or the poly crystalline silicon has high photoelectric conversion efficiency, however, it has a problem that the manufacturing cost and the setup cost are high. The thin-film solar cell for solving this problem, in particular, the thin-film solar cell using the amorphous silicon has been spotlighted, since a large-area solar cell module was manufactured at low manufacturing cost and the energy recovery term was short. However, it still has a problem that its photoelectric conversion efficiency is lower than that of the single crystalline silicon solar cell and the efficiency is further decreased when being exposed to light. Even in a solar cell using other material, it has a problem that when the conversion efficiency is high, the manufacturing cost becomes high and the energy recovery term is extended, conversely, when the unit cost of production is low and the energy recovery term is short, the photoelectric conversion efficiency is low.

In order to solve the problems of the low photoelectric conversion efficiency of the thin-film solar cell using the amorphous silicon, a structure in which semiconductor layers with different band gaps are formed with a buffer layer therebetween, has been proposed, and in particular, a structure in which the amorphous silicon (a-Si:H) and microcrystalline silicon (uc-Si:H) are stacked, having different band gaps and mismatched crystal lattices, has been proposed.

FIG. 1 is a cross-sectional view showing a stacking structure of thin-film solar cell elements according to one embodiment of the prior art.

In one embodiment of the prior art, a first solar cell layer 120 and a second solar cell layer 130 having different characteristics and crystal structures are stacked in sequence, and the two solar cell layers are electrically connected in series by connecting one transparent conductive layer 111 stacked on the second solar cell layer with the other transparent conductive layer 110 stacked below the first solar cell layer of the adjacent cell.

FIG. 2 is a diode equivalent circuit view showing a serial connection of such semiconductor layers. In general, the first solar cell layer on the side to be incident by light is made of the amorphous silicon, having high band gap energy of 1.7 to 1.9 eV, but on the other hand, the second solar cell stacked on the first solar cell layer is made of the microcrystalline silicon, having a band gap energy of about 1.1 eV. As such, the solar cell layers having different absorption bands from each other are stacked so that the photoelectric conversion efficiency, which is higher than the thin-film solar cell made of single solar cell layer such as the amorphous silicon, etc., is improved. According to the research result, it has been found that the initial photoelectric conversion efficiency is about 14.5% in a small-area module of 3 cm², and is about 12% in a large-area module.

The problem of a structure of a solar cell in which the different double solar cell layers are stacked is that the current of two solar cell layers should be designed to be identical, since the two solar cell layers are connected in series. Owing to this limitation, the thickness of the amorphous silicon intrinsic semiconductor layer, which is the first solar cell layer being positioned in the lower portion, should be formed to be thicker than is deemed necessary, and as the rate of electrical power generated from the amorphous solar cell layer is increased in proportion thereto, the whole efficiency by means of the Stabler-Wronski effect is severely decreased. To the contrary, if the thickness of the intrinsic semiconductor layer is optimized to be thin, the short-circuit current of the first solar cell layer positioned in the lower portion becomes small. Accordingly, it leads to the problem that as the difference of the short-circuit current of the two solar cell layers becomes large, the efficiency of the whole elements of the two layers connected in series becomes greatly smaller than the total of the respective efficiencies achieved in the two solar cell layers, since the short-circuit current is limited to the short-circuit current of the first solar cell layer.

In order to overcome the difficulty of the manufacturing process resulted from the difficulty in controlling the thickness of the intrinsic semiconductor layer for obtaining the optimal photoelectric conversion efficiency in the solar cell on which such different double solar cell layers are stacked, and to provide a reliable constant efficiency, U.S. Patent No. 2005/0150542 A1 has disclosed a solar cell module dividing a first solar cell layer positioned in the lower part from a second solar cell layer positioned in the upper portion with a transparent insulating layer, proposing a 4-T structure in a shape drawing two terminals from the respective solar cell layers, and thereby independently connecting the respective first and second solar cell layers with the adjacent cells in series. When using this method, there is an advantage capable of manufacturing a solar cell module of which photoelectric conversion efficiency is optimized without the necessity for considering the mismatch of the short-circuit current of the first and the second solar cell layers. However, the respective first and second solar cell layers should independently be manufactured and an insulating layer should be inserted during the process, thereby causing a problem that the manufacturing process is rather complicated and the manufacturing cost is increased.

### DISCLOSURE OF INVENTION

### Technical Problem

The object of the present invention is to provide a structure of solar cell elements with high photoelectric conversion efficiency in a thin-film solar cell module, and a method of fabricating the solar cell elements, manufacturing such a solar cell in a relatively simple process and thereby incurring smaller manufacturing cost than other thin-film silicon solar cell.

Another object of the present invention is to provide a thin-film solar cell and a fabrication method thereof, for minimizing the dissipation of electrical power by means of the mismatch of the short-circuit current in a solar cell with unit cells in a structure that two silicon solar cell layers having different characteristics and having large difference in circuit-short current are stacked.

Another object of the present invention is to provide a method of simply fabricating thin-film solar cell elements through a successive manufacturing process so that the complexity in the manufacturing process of the prior art due to a separate process to independently manufacture the first and the second solar cell layers and to connect them, etc., is solved and the high photoelectric conversion efficiency can be obtained in a solar cell with unit cells in a structure that two silicon solar cell layers having different characteristics and having large difference in circuit-short current are stacked.

### Technical Solution

In order to achieve the above objects, a thin film solar cell according to the present invention comprises a unit cell of a first solar cell layer with a multifunction structure and a second solar cell layer, which are mutually electrically connected in parallel.

According to the present invention, it is preferable that at least one the unit cell be included, the cell being connected in serial.

According to the present invention, it is preferable that the first solar cell layer and the second solar cell layer use one solar cell layer independently selected from an amorphous silicon solar cell layer or a microcrystalline silicon solar cell layer, respectively.

According to the present invention, it is preferable that the amorphous silicon solar cell layer include an amorphous silicon p-layer, an amorphous silicon i-layer and an amorphous silicon n-layer, which are sequentially stacked.

According to the present invention, it is preferable that the microcrystalline silicon solar cell layer include a microcrystalline silicon p-layer, a microcrystalline silicon i-layer and a microcrystalline silicon n-layer, which are sequentially stacked.

According to the present invention, it is preferable that the first solar cell layer and the second solar cell layer use a common electrode.

According to the present invention, it is preferable that a transparent insulating layer at adjacent portions of each cell be further included to be electrically insulated.

A method for fabricating a thin film solar cell according to the present invention comprises: connecting unit cells formed on a substrate in series with a transparent conductive layer, wherein the each unit cell comprises a first solar cell layer and a second solar cell layer mutually connected in parallel; forming a back side electrode layer on the second solar cell layer; and electrically insulating the second solar cell layer each other.

According to the present invention, it is preferable that a step for forming the unit cell connected in parallel comprises; forming a transparent conductive layer electrically connecting a lower layer of the first solar cell layer formed on the substrate and an upper layer of the other first solar cell layer separately formed from the first solar cell layer; and forming a plurality of second solar cells separately on the first solar cell layer and the transparent conductive layer.

### Advantageous Effects

The present invention as described above provides a structure of a thin-film solar cell device with high photoelectric conversion efficiency and good reliability, and allows fabrication of a solar cell of a large-area through a relatively simple series of fabricating processes with a low manufacturing cost.

Also, by proposing a structure of a solar cell and a fabrication method thereof, having high photoelectric conversion efficiency and enabling fabrication of a large-area and at a low manufacturing cost, the present invention will contribute to the environmental conservation of the earth as next generation clean energy source as well as create enormous economic worth by being directly applied to various fields such as public, civil and military facilities.

### BRIEF DESCRIPTION OF THE DRAWINGS

Other objects and aspects of the present invention will become apparent from the following description of embodiments with reference to the accompanying drawings in which:

FIG. 1 is a cross-sectional view showing a stacking structure of thin-film solar cell elements according to one embodiment of the prior art.

FIG. 2 is a diode equivalent circuit view of thin-film solar cell elements according to one embodiment of the prior art.

FIG. 3 is a cross-sectional view showing a stacked structure of thin-film solar cell elements according to the present invention.

FIG. 4 is a diode equivalent circuit view of thin-film solar cell elements according to the present invention.

FIG. 5 is a graph showing the relation of short-circuit current density-to-voltage between the thin-film solar cell elements according to one embodiment of the present invention and the thin-film solar cell elements according one embodiment of the prior art.

FIG. 6 is a graph showing the relation of efficiency-to-voltage between the thin-film solar cell elements according to one embodiment of the present invention and the thin film solar cell elements according one embodiment of the prior art.

FIG. 7 to FIG. 21 are cross-sectional views of a stacked structure of elements showing a fabrication method of a thin-film solar cell according to one embodiment of the present invention according to process steps.

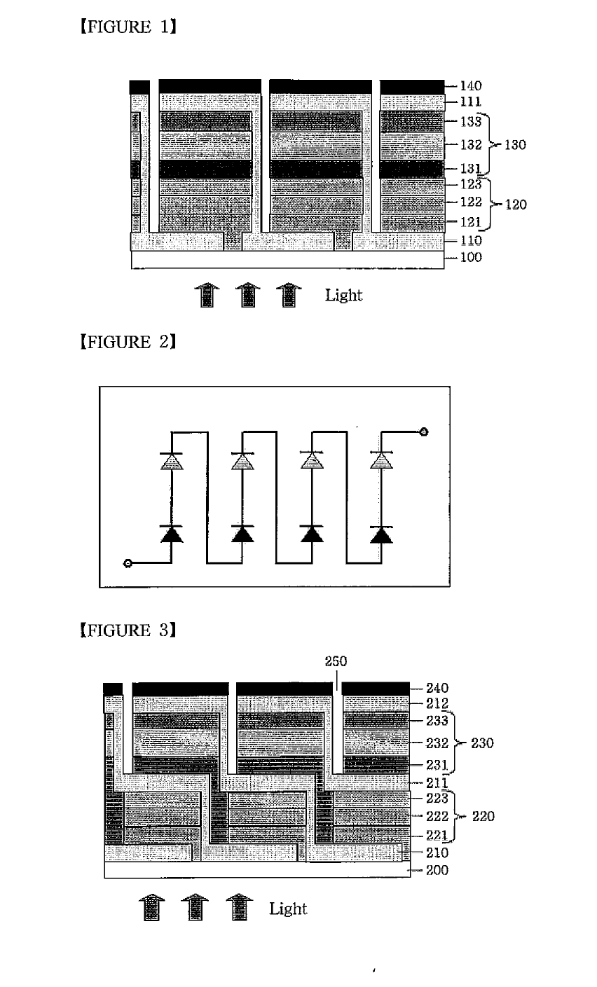

### MODE FOR THE INVENTION

Hereinafter, preferred embodiments of the present invention will be described with reference to the drawings In designating reference numbers to components in the following drawings, the same reference numbers indicate the same components in different figures. The detailed description of known functions and configurations will be omitted so as not to obscure the subject of the present invention with unnecessary detail.

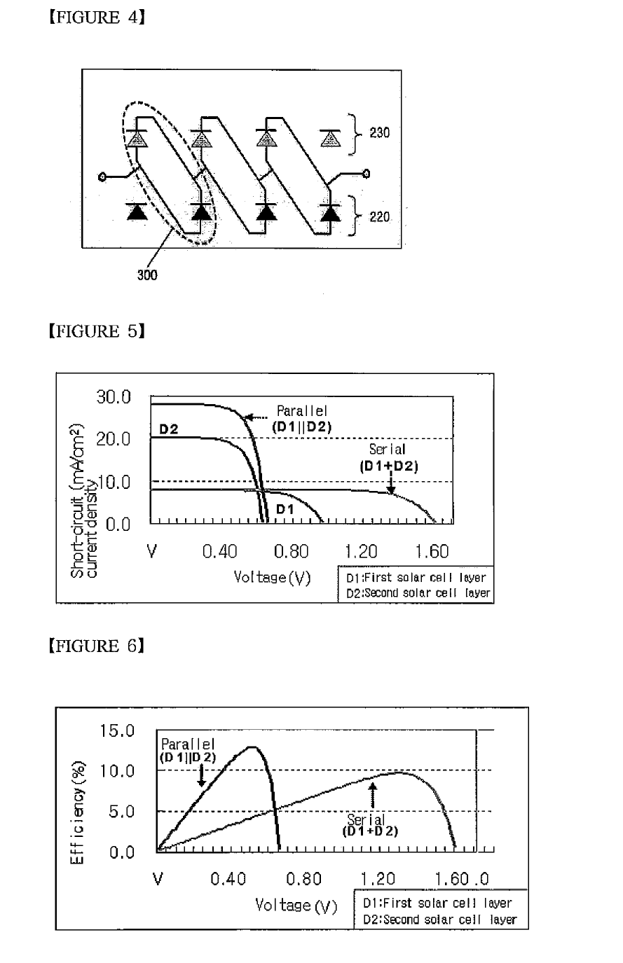

FIG. 3 is a cross-sectional view showing a stacked structure of thin-film solar cell elements according to the present invention, and FIG. 4 is a diode equivalent circuit view constructed in the thin-film solar cell elements according to the present invention.

In the embodiment, the thin-film solar cell elements comprise a glass substrate 200, a first solar cell layer 220, a second solar cell layer 230, transparent conductive layers 210, 211 and 212, a back side electrode layer 240 and a transparent insulating layer 250.

According to the present embodiment, the thin-film solar cell elements have the repeat unit comprising a first transparent conductive layer formed on a substrate, a first solar cell formed on the first transparent conductive layer, a second transparent conductive layer formed on the first solar cell, a second solar cell formed on the second transparent conductive layer and an upper electrode layer thereon. The repeat units are coupled in serial each other.

In a preferred embodiment, the upper electrode layer comprises a third electrode layer, and the repeat units are coupled in serial each other by the first transparent conductive layer, the second transparent conductive layer and the third transparent conductive layer.

The embodiment schematically shows a method of connecting the first solar cell layer with the second solar cell layer.

Referring to FIG. 3, the thin-film solar cell forms a unit cell that one solar cell layer formed in a multi-junction structure and the other solar cell layer are electrically connected each other in parallel.

The parallel connection of the unit cell is implemented by connecting the p layer of the first solar cell layer with the p layer of the second solar cell layer with the transparent conductive layer, and connecting the n layer of the first solar cell layer with the n layer of the second solar cell layer with the transparent conductive layer.

The solar cell layer is configured of one sort of solar cell layer selected from respective crystal based silicon solar cell layer or amorphous silicon solar cell layer, and preferably the crystal based silicon solar cell layer uses a microcrystalline silicon solar cell layer.

The solar cell layer configured of the amorphous silicon solar cell layer forms any one of a pn-type junction structure of amorphous silicon and a pin-type junction structure of amorphous silicon.

The solar cell layer configured of the microcrystalline silicon solar cell layer forms any one of a pn-type junction structure of microcrystalline silicon and a pin-type junction structure of microcrystalline silicon.

One or more unit cells internally connected in parallel are grouped to be electrically connected in series, forming a large-area integrated thin film solar cell. The serial connection between the unit cells includes the transparent insulating layer 250 between the adjacent unit cells.

In other words, the lower transparent conductive layer (such as TCO) 210 is stacked on the substrate (such as glass substrate) 200, and the first solar cell layer 220 on which a p-type 221, an i-type 222 and an n-type 223 amorphous silicon layers are stacked in sequence is mounted thereon. The middle transparent conductive layer 211 is stacked again on the first solar cell layer, and the second solar cell layer 230 on which a p-type 231, an i-type 232 and an n-type 233 microcrystalline silicon layers are stacked in sequence is mounted thereon, Continuously, the upper transparent conductive layer 212 and the back side electrode layer 240 are stacked.

The middle transparent conductive layer 211 stacked on the n layer of the first solar cell layer positioned in the lower portion due to the cross-sectional structure of the thin-film solar cell is connected with the upper transparent conductive layer 212 stacked on the n layer of the second solar cell layer positioned in the upper portion of the adjacent solar cell layer, thereby being connected.

The lower transparent conductive layer 210 stacked on the p layer of the first solar cell layer positioned in the lower portion due to the cross-sectional structure of the thin-film solar cell is connected with the middle transparent conductive layer 211 stacked below the p layer of the second solar cell layer positioned in the upper portion of the adjacent solar cell layer, thereby being electrically connected. As a result, it becomes a structure in which the second solar cell layer positioned in the upper portion by being adjacent to the first solar cell layer positioned in the lower portion in the thin-film solar cell is internally connected in parallel, as one unit cell.

In the embodiment, the thin-film solar cell elements includes the structure to form gaps between the cells by performing a cutting process in a pattern on the back side electrode layer 240, the upper transparent conductive layer 212, and the p layer of the second solar cell layer 230, from the top in sequence, so as to allow the adjacent unit cells to be electrically connected therebetween in series by making the air layer of these gaps the transparent insulating layer 250.

The process inducing photovoltaic force from the thin-film solar cell elements is initialized, while the light incident through the substrate passes through the p-type silicon layer of the first solar cell layer or the second solar cell layer to be absorbed in the i-type silicon layer thereof.

If the light to be incident has larger energy than the optical band gap of the amorphous silicon or the microcrystalline silicon, electrons are excited and a pair of electrons-holes is generated so that the generated electrons and holes each are divided into the n-type silicon layer and the p-type silicon layer so that they can move. Therefore, if the photovoltaic force generated between both electrode ends of p-type and n-type silicon layers is connected with an external circuit, it acts as a solar cell.

Referring to an equivalent circuit view in FIG. 4, photovoltaic force is induced from the first solar cell layer 220 positioned in the lower portion and the second solar cell layer 230 positioned in the upper portion, respectively, the respective common electrodes of these solar cell layers are connected with each other with the transparent conductive layer to form a unit cell 300 connected in parallel and on the whole several of the unit cells 300 are connected with the external circuit in a structure that they are connected with the transparent conductive oxide in series, thereby acting as a solar cell.

Referring to FIG. 3 and FIG. 4, the embodiment of the present invention minimizes the dissipation of electrical power which is caused when the microcrystalline silicon layer and the amorphous silicon layer, having a large difference in the short-circuit current, are stacked to be directly connected with each other in series.

In other words, the microcrystalline silicon layer is stacked on the upper portion as the second solar cell layer and the amorphous silicon layer is stacked on the lower portion as the first solar cell layer, wherein the two solar cell layers are connected with each other in parallel, and these structures being connected in series, thereby minimizing the dissipation of electrical power and maintaining the high photoelectric conversion efficiency of the silicon stacked structure.

The embodiment is the structure to form an electrical parallel connection, while maintaining the stacked structure of the two different solar cell layers, as well as to control an inter-layer structure through a patterning using order of deposition and cutting process within the fabrication method of the present invention. Therefore, it is convenient for manufacturing, since the structure can be formed without adding any separate independent process.

FIG. 5 is a graph showing a change of short-circuit current density for voltage between the thin-film solar cell elements according to one embodiment of the present invention and the thin-film solar cell elements according to one embodiment of the prior art configured of double solar cell layers of the amorphous and the microcrystalline silicon layers, wherein they are connected with each other in series. FIG. 6 is a graph showing the photoelectric conversion efficiency with respect to the voltage.

The graph is a graph showing the result of performing numerical analysis for comparing the efficiency between the thin-film solar cell element of the prior art and that of the present invention.

Referring to FIG. 5 and FIG. 6, for the first solar cell layer made of the amorphous silicon and positioned on the lower portion (represented as D1 on the graph), it is assumed that open voltage V is 0.98V, short-circuit current density is 8.0 mA/cm² and at this time, photoelectric conversion efficiency is about 5.3%.

Also, for the second solar cell layer made of the microcrystalline silicon and positioned on the upper portion (represented as D2 on the graph), it is assumed that open voltage is 0.64V, short-circuit current density is 20 mA/cm² and photoelectric conversion efficiency is about 8.8%.

In the case that the two solar cell layers are connected with each other in series in a prior art manner (represented as D1+D2 on the graph), it is represented that voltage is 1.62V, short-circuit current density is 8.0 mA/cm² and photoelectric conversion efficiency is about 9.7%.

From the above, it is shown that the whole short-circuit current density is limited to 8.0 mA/cm², which is the short-circuit current of the first solar cell layer, according to the difference in the short-circuit current between the amorphous silicon layer and the microcrystalline silicon layer, and thereby, the photoelectric conversion efficiency of the whole elements does not get close to reaching 14.1%, which is the total of the respective efficiencies achieved in the first and the second solar cell layers, resulting in that the efficiency is not so high.

However, in the case that the two solar cell layers are connected with each other in parallel according to one embodiment of the present invention (represented as D1∥D2 on the graph), it is represented that voltage is 0.66V, short-circuit current density is 28 mA cm² and photoelectric conversion efficiency is about 12.9%. Therefore, the efficiency is increased by about 3.2% more than the case connected in series in the prior art.

According to the present invention, since the double silicon stacked structure can achieve a higher photoelectric conversion efficiency than the structure of the solar cell elements configured of a single silicon layer in the prior art, and the high photoelectric conversion efficiency can be achieved in the parallel connection structure between the solar cell layers rather than in the series connection structure therebetween in a solar cell module formed in a multi-stacked structure, it is very significant in terms of manufacturing the thin-film solar cell elements in a double silicon stacked structure.

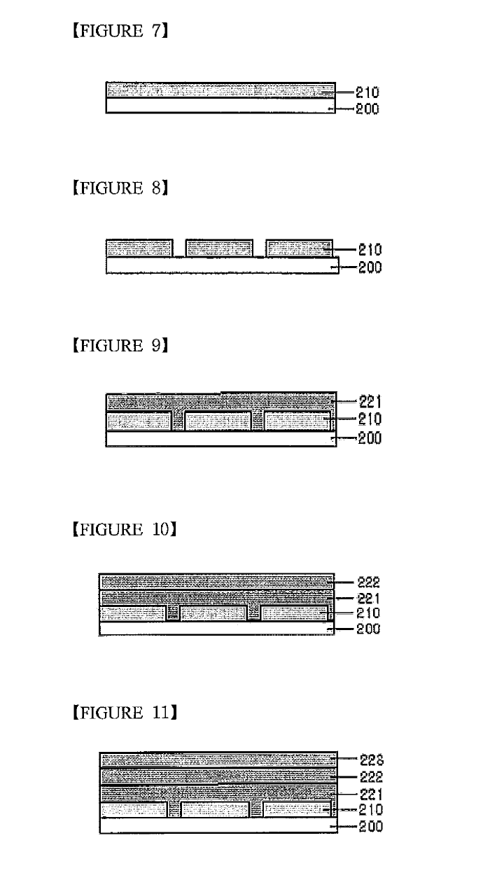

FIG. 7 to FIG. 21 are cross-sectional views of a stacked structure of elements showing a fabrication method of a thin-film solar cell according to one embodiment of the present invention according to process steps.

Referring to FIG. 7 to FIG. 21, a fabrication method of a thin-film solar cell according to one embodiment of the present invention includes the steps of: depositing a transparent conductive oxide on a glass substrate; depositing a first solar cell layer with an amorphous silicon layer; depositing a second solar cell layer with a microcrystalline silicon layer after depositing the transparent conductive oxide again, and continuously depositing a back side electrode layer after depositing the transparent conductive oxide again.

Referring to FIG. 7, the fabrication method of the thin-film solar cell according to one embodiment of the present invention is initiated with the step of depositing a low transparent conductive oxide 210 on the glass substrate 200.

Next, referring to FIG. 8, the low transparent conductive oxide 210 is cut in a pattern through a cutting process, and a p-type amorphous silicon layer 221 (a-Si:H) is deposited on the low transparent conductive oxide 210 as shown in FIG. 9.

The i-type amorphous silicon layer 222 (a-Si:H) is deposited on the p-type amorphous silicon layer 221 as shown in FIG. 10, and an n-type amorphous silicon layer 233 (a-Si:H) is deposited on the i-type amorphous silicon layer 222 as shown in FIG. 11.

In one embodiment of the present invention, the publicly known methods can be used as a deposition method of the amorphous silicon layer. It is preferable to use one selected from a sputtering method, a high frequency plasma chemical vapor deposition method, a microwave plasma chemical vapor deposition method, a thermal chemical vapor deposition method and a low pressure chemical vapor deposition method (LPCVD), etc.

In particular, in the case of the amorphous silicon, it is common to use the plasma chemical vapor deposition method (PECVD) using silane gas, etc. wherein the PECVD decomposes a source gas by means of plasma and then deposits it on a gaseous state.

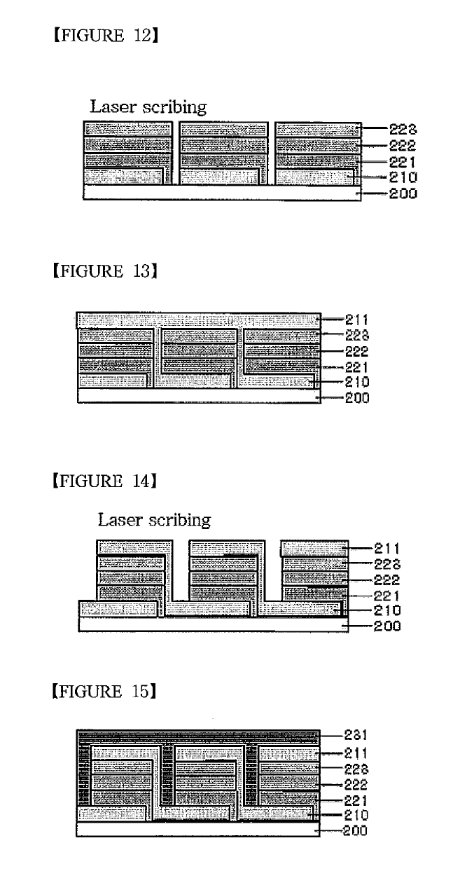

In the embodiment, referring to FIG. 12, the first solar cell layer 220 configured of the pin-type amorphous silicon layeris patterned by the cutting process, the middle transparent conductive oxide 211 is deposited after the patterning as shown in FIG. 13, and up to a p layer 221 of the low solar cell layer 220 including the middle transparent conductive oxide 211 is partly patterned by the cutting process as shown in FIG. 14.

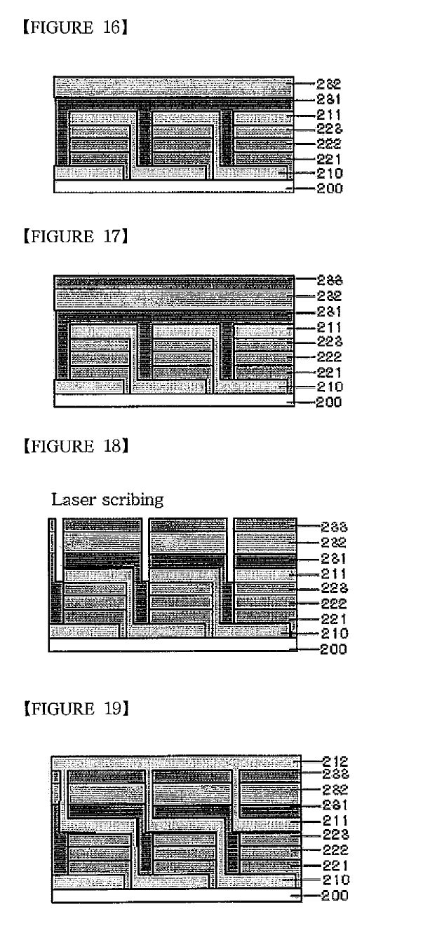

Next, referring to FIG. 15, a p-type microcrystalline silicon layer 231 (us-Si:H) is deposited after the patterning, an i-type microcrystalline silicon layer 232 (usc-Si:H) is deposited on the p-type microcrystalline silicon 231 as shown in FIG. 16, and thereafter, an n-type microcrystalline silicon layer 233 (uc-Si:H) is deposited on the i-type microcrystalline silicon layer 232 as shown in FIG. 17.

In the same manner, the microcrystalline silicon layer can be rapidly deposited at a relatively low temperature using the plasma chemical vapor deposition method.

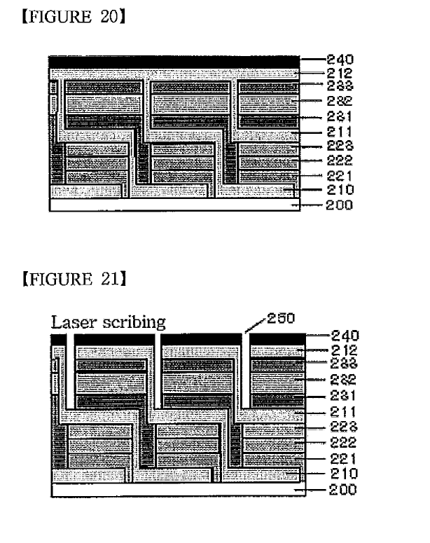

In the embodiment, referring to FIG. 18, up to the middle transparent conductive oxide 211 including the second solar cell layer 230 configured of the pin-type microcrystalline silicon layeris partly patterned by the cutting process, and thereafter, the upper transparent conductive oxide 212 is deposited after the patterning as shown in FIG. 19 and a back side electrode layer 240 is deposited on the upper transparent conductive oxide 212 as shown in FIG. 20.

The respective lower 210, middle 211 and upper 212 transparent conductive oxides are merely divided according to the positions in a cross-sectional view of the solar cell elements to be stacked for convenience, and thus all of them can be deposited using the same material and method. Furthermore, they can be formed through a publicly known deposition method by using publicly known material, which can be used as a conductive oxide that is easily known by those skilled in the technical field of the present invention. In particular, it is preferable that they are made of the transparent and conductive material such as tin oxide (SnO₂) and indium oxide (ITO).

The back side electrode part 240 can be formed by using publicly known material and method, which are usually used in an electrode layer that is easily known by those skilled in the technical field of the present invention. In particular, it is preferable to fabricate a metal layer with aluminum (Al), silver (Ag), titanium (Ti), and palladium (Pd), etc., using a method of screen printing and spraying, etc. During a method of screen printing silver paste (Ag paste), stabilizing and drying in an oven is required, and as such heat treating is usually used.

In the embodiment, the fabrication method of the thin-film solar cell further includes the process that up to a p layer 231 of the second solar cell 230 is partly patterned by the cutting process, and includes the back side electrode layer 240 and the upper transparent conductive oxide 212.

The cutting process forms minute gaps between the adjacent unit cells and the air layer in the gaps may act as the transparent insulating layer 250.

The cutting process used in the embodiment of the present invention can be performed by a publicly known conventional cutting method that is easily known by those skilled in the technical field of the present invention. Any one of a laser scribing method, a wet etching method, a dry etching method, a lift-off method, and a wire mask method is commonly used.

In the embodiment of the present invention, particularly, it is preferable to apply the so-called laser scribing method to a thin film solar cell module, whereby a pulsed laser light is scanned across a substrate and a thin-film on the substrate is processed, i.e., patterned.

According to the thin-film solar cell and the fabrication method thereof, with the stacked arrangement and structure as described above, it is possible to electrically connect the second solar cell layer made of continuously arranged microcrystalline silicon and positioned in the upper portion, and the first solar cell layer positioned in the lower portion just next to the second solar cell layer in a view of structure and made of amorphous silicon, in one unit cell in parallel.

And, the parallel connection structure of these unit cells contacts other parallel connection structure of neighboring unit cells, forming a module structure in which the parallel structures are connected with each other in series.

Consequently, these structures adopt a structure in which the transparent conductive oxides of upper, middle and low are neither directly connected with the transparent conductive oxides of upper, middle and low of neighboring cells, respectively, nor connected only in series by forming an insulating layer between the unit cells as shown in the conventional publicly known technique.

Also, by forming an insulating layer such that electricity is not communicated between the unit cells, particularly, an insulating layer made of an air layer, in the upper transparent conductive oxide connected with the middle transparent conductive layer of neighboring cells through the second solar cell layer positioned in the upper portion, the electrical insulation of the connected transparent conductive oxide is improved to divide the unit cells, implementing the serial connection of the unit cells.

Although a few embodiments of the present invention have been shown and described, it would be appreciated by those skilled in the art that changes might be made in this embodiment without departing from the principles and spirit of the invention, the scope of which is defined in the claims and their equivalents.

### INDUSTRIAL APPLICABILITY

The present invention as described above provides a structure of a thin-film solar cell device with high photoelectric conversion efficiency and good reliability, and allows fabrication of a solar cell of a large-area through a relatively simple series of fabricating processes with a low manufacturing cost.

1. A thin film solar cell comprising a unit cell of a first solar cell layer with a multijunction structure and a second solar cell layer, which are mutually electrically connected in parallel.

2. The thin film solar cell of claim 1, wherein at least one the unit cell is included, the cell being connected in serial.

3. The thin film solar cell of claim 1 or 2, wherein the first solar cell layer and the second solar cell layer are one solar cell layer selected independently from an amorphous silicon solar cell layer or a microcrystalline silicon solar cell layer, respectively.

4. The thin film solar cell of claim 3, wherein the amorphous silicon solar cell layer includes an amorphous silicon p-layer, an amorphous silicon i-layer and an amorphous silicon n-layer, which are sequentially stacked.

5. The thin film solar cell of claim 3, wherein the microcrystalline silicon solar cell layer includes a microcrystalline silicon p-layer, a microcrystalline silicon i-layer and a microcrystalline silicon n-layer, which are sequentially stacked.

6. The thin film solar cell of claim 1 or 2, wherein the first solar cell layer and the second solar cell layer use a common electrode.

7. The thin film solar cell of claim 2, further comprising: a transparent insulating layer at adjacent portions of each cell to be electrically insulated.

8. A thin film solar cell comprising at least one repeat unit comprising: a first transparent conductive layer formed on a substrate, a first solar cell formed on the first transparent conductive layer, a second transparent conductive layer formed on the first solar cell, a second solar cell formed on the second transparent conductive layer and an upper electrode layer thereon.

9. The thin film solar cell as set forth in claim 8, wherein the first solar cell is an amorphous silicon or a microcrystalline silicon.

10. The thin film solar cell as set forth in claim 8, wherein the second solar cell is an amorphous silicon or a microcrystalline silicon.

11. The thin film solar cell as set forth in claim 9 or 10, wherein p, i, and n-type amorphous silicon or microcrystalline silicon are sequentially formed.

12. A thin film solar cell comprising repeat units comprising: a first transparent conductive layer formed on a substrate, a first solar cell formed on the first transparent conductive layer, a second transparent conductive layer formed on the first solar cell, a second solar cell formed on the second transparent conductive layer and an upper electrode layer thereon, wherein the repeat units are coupled in serial each other.

13. The thin film solar cell as set forth in claim 1, wherein the upper electrode layer comprises a third electrode layer.

14. The thin film solar cell as set forth in claim 13, wherein the unit cells are coupled in serial each other by the first transparent conductive layer, the second transparent conductive layer and the third transparent conductive layer.

15. A method for fabricating a thin film solar cell, comprising:
connecting unit cells formed on a substrate in series by intermediation of a transparent conductive layer, wherein the each unit cell comprises a first solar cell layer and a second solar cell layer mutually connected in parallel;
forming a back side electrode layer on the second solar cell layer; and
electrically insulating the second solar cell layer each other.

16. The method for fabricating a thin film solar cell of claim 15, wherein the unit cell connected in parallel is formed by a process comprising the steps of;
forming a transparent conductive layer electrically connecting a lower layer of the first solar cell layer formed on the substrate and an upper layer of the other first solar cell layer separately formed from the first solar cell layer; and
forming a plurality of second solar cells separately on the first solar cell layer and the transparent conductive layer.

17. The method for fabricating a thin film solar cell of claim 15, wherein the first solar cell layer and the second solar cell layer are one solar cell layer selected independently from an amorphous silicon solar cell layer or a microcrystalline silicon solar cell layer, respectively.

18. The method for fabricating a thin film solar cell of claim 15, wherein the amorphous silicon solar cell layer includes an amorphous silicon p-layer, an amorphous silicon i-layer and an amorphous silicon n-layer, which are sequentially stacked.

19. The method for fabricating a thin film solar cell of claim 15, wherein the microcrystalline silicon solar cell layer includes a microcrystalline silicon p-layer, a microcrystalline silicon i-layer and a microcrystalline silicon n-layer, which are sequentially stacked.

20. The method for fabricating a thin film solar cell of claim 15, wherein the first solar cell layer and the second solar cell layer use a common electrode.
